(19) United States
(12) Patent Application Publication
(10) Pub. No.: US 2010/0140750 A1
(43) Pub. Date: Jun. 10, 2010

(54) Parallel Plane Memory and Processor Coupling in a 3-D Micro-Architectural System

(75) Inventor: Thomas R. Toms, Dripping Springs, TX (US)

Correspondence Address: QUALCOMM INCORPORATED, 5775 MOREHOUSE DR., SAN DIEGO, CA, 92121, US

(73) Assignee: QUALCOMM Incorporated, San Diego, CA (US)

(21) Appl. No.: 12/332,302

(22) Filed: Dec. 10, 2008

(51) Int. Cl. H01L 21/98; H01L 23/538

(52) U.S. Cl. 257/621; 438/455; 257/E23.173; 257/E21.705

(57) ABSTRACT

An IC device is constructed in a manner that allows for the memory and processor elements to be positioned one above the other on parallel planes of a 3-D structure. Interconnections between the memory(s) and the processor(s) are accomplished by using through substrate stacking (TSS) techniques. This arrangement provides the processor with direct access to the memory by reducing the distance between the memory and the processor.

### TECHNICAL FIELD

This disclosure generally relates to multi-plane (3-D) processing structures and more particularly to enhancing coupling between memory elements and processing elements in such structures.

### BACKGROUND

Computer processing systems require a close coupling between memory and processing elements and thus those elements are built on the same chip. In terms of physical distance, the closer the memory can be to the processing element that uses that memory, the better the bandwidth the system will have. Better bandwidth brings with it lower latency and higher performance, which in turn leads to less energy usage.

Because in conventional chips memories and their respective microprocessors occupy the same physical plane, it is not always possible to locate all of the memories immediately adjacent to their respective processors. In current systems, the memory elements are connected to their respective micro-processor elements by one or more buses constructed in the same plane of material in which the memory and processor are constructed. In situations where the memory is external to the processor, the buses interconnecting the memory and the processor are even longer.

Tezzaron Semiconductor has disclosed a product that interfaces a memory separate from a processor. The memory and processor are stacked, enabling high performance. In one product, the memory storage elements are constructed on a tier(s) that is stacked to form the memory array's storage elements. These storage elements are in turn combined with other memory functions which may be located on separate tier(s) to form a memory subsystem. These other memory functions include: decode, write, read, error correction, repair bad blocks, etc. In another product, the memories are standard off the shelf memories where all of the memory functions are contained within a tier, but the memories are stacked to expand the total available memory. This can be achieved by several means, such as addressing to select a subset of the memories in the stack data bus where each memory in the stack provides a subset of the data bus width.

These memories are in the nature of cache memories, which require very little structure between the memory and the processor. Register memories, on the other hand, require higher connectivity than do cache memories because the register memories have multiple inputs and outputs to handle functions such as floating point math, etc. That is one reason why micro-processor memories, such as registers, are typically constructed in close coupled relationship with their respective micro-processors.

### BRIEF SUMMARY

The present disclosure is directed to systems and methods which allow for the memory and processor elements to be positioned one above the other on parallel planes of a 3-D structure. Interconnections between the memory(s) and the processor(s) are accomplished by using through silicon stacking (TSS) techniques. This arrangement provides the processor with direct access to the memory by reducing to a minimum the distance between the memory and the processor.

In one embodiment, a first semi-conductor tier is constructed having therein a first set of elements of a pipeline stage. A second semi-conductor tier is constructed having therein a second set of elements of the pipeline stage. The first and second semi-conductor tiers are then bonded to form at least a portion of the IC device. The first and second element sets are arranged such that when the tiers are bonded, close-coupled communication is enabled. If desired, the different tiers can be constructed having different processes, each process suited to the character of the elements being constructed therein.

In other embodiments, state memory (pipe state memory), configuration memory or scan memory can be constructed in a stacked configuration tier. By moving these memories to a tier, control/power timing issues for the processor engine are enhanced and optimized for increased performances.

The foregoing has outlined rather broadly the features and technical advantages of the present invention in order that the detailed description that follows may be better understood. Additional features and advantages will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawing, in which:

FIG. 1 shows a conventional 2-D memory and processor system.

FIG. 2 shows one embodiment of a parallel plane memory and processor system.

FIG. 3 shows one embodiment of a system for allowing the elements on the various planes to communicate with each other.

FIG. 4 shows one embodiment of a process for constructing IC devices.

### DETAILED DESCRIPTION

FIG. 1 shows a conventional 2-D memory and processor system 10. The system 10 has micro-engines 11 and 14 and memories 12 and 13. The micro-engine 11 is connected to the memory 12 by a bus 15 and connected to the memory 13 by a bus 16. The micro-engine 14 is connected to the memory 13 by a bus 17. Memories 12 and 13 can be dedicated memory register files. Because the memory and the processor are physically separate but constructed in the same tier, all of the memory calls and responses need to flow over one or the other of the buses 15 or 16. Because the individual memory cells are spread across the memory, the bus length is different for each memory cell that is accessed. This adds a latency to each memory access because each access has to propagate by its Manhattan distance. For timing purposes, all of the accesses are delayed to accommodate the longest latency. Latency in memory operations induces an energy penalty as well.

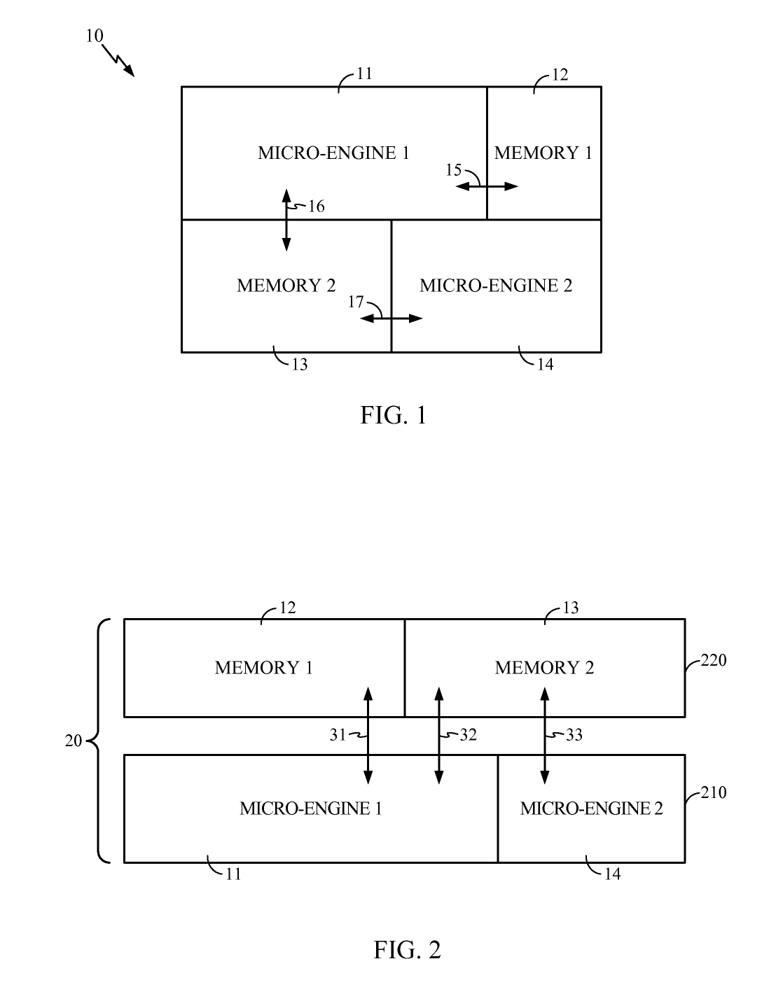

FIG. 2 shows one embodiment 20 of a parallel plane memory and processor system using the inventive techniques. Note that while the discussion herein is focused on micro-architectures (micro-engines), such as a micro-processor and a register memory structure integral therewith, the concepts discussed can be extended to any groupings of elements that require close inter-element coupling.

The embodiment 20 shows one arrangement for dividing the two dimensional structure of FIG. 1 into multiple tiers. FIG. 2 shows two such tiers, but any number of tiers can be used, if desired. Tier 1 210 has micro-engines 11 and 14 thereon while tier 2 220 includes the memories 12 and 13. Note that while it would be advantageous from an organization and manufacturing point of view to keep all of the same element types (such as memories, or processors) on the same tier, this need not be the case and the tiers can be mixed and matched if desired. Also, more than one tier can be used for an element type. For example, tiers with processors (or other elements) can sandwich a memory tier.

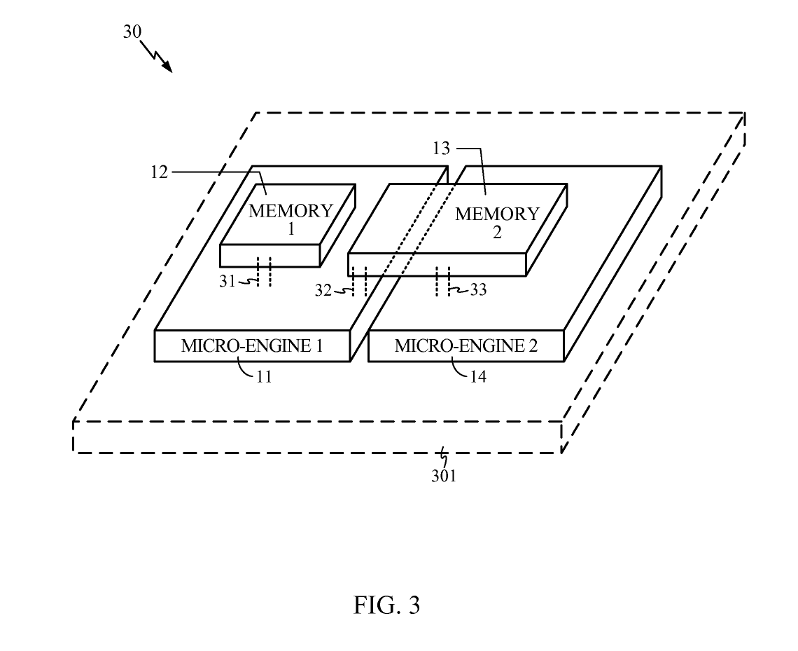

FIG. 3 shows one embodiment 30 of a system for allowing the elements on the various planes (tiers) within an IC device 301 to communicate with each other. The buses 15, 16, 17 on a 2-D single tier architecture (FIG. 1) extending in the X and Y directions, have been replaced by buses 31, 32 and 33 running in the Z direction. In one embodiment, the buses 31, 32, 33 are through silicon vias (TSVs). In another embodiment, the buses 31, 32 and 33 are direct die-to-die bonding structures. The exact connection structure depends on whether the tier configuration is a face-to-face bonding, face-to-back bonding or back-to-back bonding.

Because the memory (on tier 2) associated with the first processor of tier 1 can be layered in parallel directly above (or below) the processor, because connections between the processor and the memory can be distributed over several connections, and because the tier to tier connectivity routing will be no more than a tier thickness (e.g., 20-200 micro-meters), the latency can be reduced and the speed of operation can be increased. The second processor on tier 1 can be constructed independent from the first processor, and can be connected to its memory through its own set of connections. Thus, the second processor and it associated memory also can be optimized for speed of operation. In some situations, more than one processor can have connections to a particular memory (and vice versa), thus again increasing speed of operation.

The memories and processors are on different tiers, and accordingly need not be manufactured concurrently with each other. This then allows the fabrication of each element to be tailored to that element. For example, tier 1 can have its own manufacturing process, for example, a high performance process optimized to yield high speed processors. Tier 2 could be manufactured in a manner that yields low current leakage.

As discussed above, it is not necessary that all of the memory be located on separate tiers. Thus, some of the memory can share a tier (2-D layout) with some of the processors if desired. By using parallel stacking of elements that would normally be closely coupled in a single tier, the control and data paths between the coupled elements can be shortened. This is particularly important for register memories associated with micro-processors. For example, a register file in a floating core unit might have two write ports so that multiple processor outputs can simultaneously write to the register. The register could have 4, 6 or 8 read ports so that it can be accessed by different parts of the floating core unit as necessary without data collisions. These registers may be located on the same tier and adjacent its associated processor. Other memory used by the processor may be located on a different tier.

In the embodiment shown in FIG. 3, it is assumed that the active faces of each tier have a silicon (Si) substrate that physically separates the active faces from each other. In other words, a face-to-back or back-to-back configuration exists. In such an embodiment, through silicon vias (TSVs) such as vias 31, 32, and 33, can provide the interconnections. In situations where it is desired to place the active faces adjacent to each other, the TSVs are not required, but a die-to-die (D2D) bond can be used which allows contacts formed in one die to electronically mate with contacts formed in the other die without requiring TSVs.

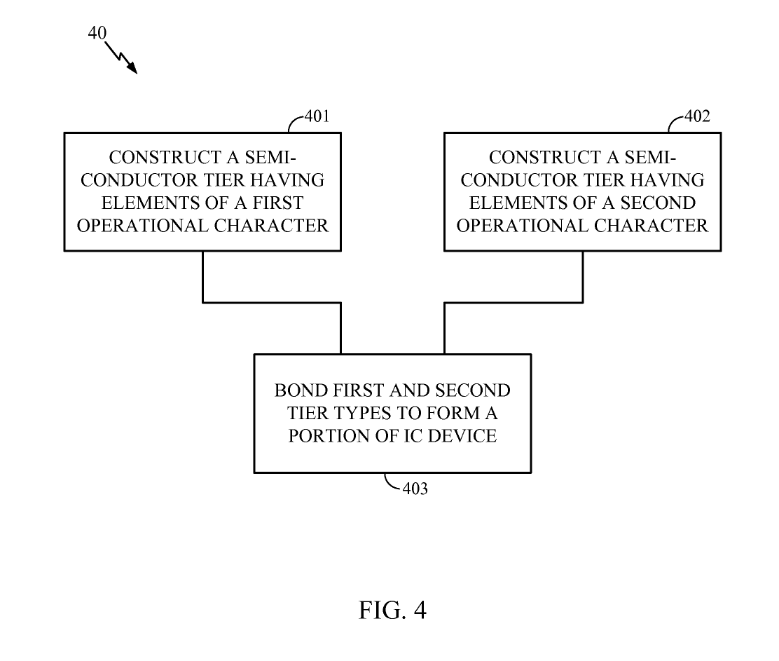

FIG. 4 shows one embodiment 40 of a process for constructing IC devices. Block 401 constructs a first semi-conductor tier having therein a first set of elements. The first elements have a defined operational character, such as memory, micro-processor, etc. Block 402 constructs a second semi-conductor tier having therein a second set of elements. The second set of elements may be different in operational character (i.e., memory, processor, etc.) from the first set of elements. For example, an analog function may be constructed on the first tier, while an associated digital controller is constructed on the second tier. In one embodiment, the second set of elements are similar to the first set of elements, but should be closely coupled together.

In another embodiment, each different tier includes components of a single pipeline stage. For example, one tier could include storage elements (for example, the input and output registers) while another tier includes the operator (for example an arithmetic logic unit (ALU)). The tiers are arranged so the operators are physically close to the operands. In the case of executing the operation A+B=C, the input operands on the first tier are passed to the second tier for adding together. The result is then stored on the first tier. According to this embodiment, because the operands are decoupled from the operator, each can be optimized appropriately. For example, the tier storing the operands could be optimized for stability, whereas the tier with the arithmetic logic unit could be optimized for speed.

Block 403 bonds the first and second semi-conductors together to form at least a portion of the IC device. The bonding is performed in such a manner so as to facilitate close-coupled communication between certain of the first and second element sets. This coupling could be, for example, by using through silicon stacking (TSS) technology with respect to at least one of the semi-conductors. Also note that, as discussed above, blocks 401 and 402 can be different processes each suited to the character of the elements being constructed therein.

Note that while the example discussed herein illustrates the use of a register file (data) memory, any of a number of different memory types can employ the concepts discussed herein. For example, configuration memory, scan memory and the like, can be built in one or more tiers which would improve memory control and/or timing issues between the tiered memory and processor located on a parallel tier. Because the memory could then be “spread” physically in parallel with the processor, various control leads (connections) and power connections can be positioned to reduce latency across the memory due to differences in lead lengths. Both the processor and the memory can have multiple interconnection points along the common portion of their respective parallel lengths.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An IC device comprising:
a first tier having constructed therein a first portion of a micro architecture;
a second tier having constructed therein a second portion of said micro architecture, said first and second portions requiring close communication; and
a series of connections enabling communication between said first and second portions.

2. The IC device of claim 1 wherein the first portion comprises a first portion of a pipeline stage; and the second portion comprises a second portion of the pipeline stage.

3. The IC device of claim 1 wherein said micro architecture comprises at least one memory element and at least one micro-processor element.

4. The IC device of claim 3 wherein said memory element is a register utilized by said micro-processor element.

5. The IC device of claim 1 wherein said series of connections comprise through silicon vias (TSVs).

6. The IC device of claim 1 wherein said first and second portions of said micro-architecture are manufactured under processes independent from each other.

7. A method for constructing an IC device, said method comprising:
constructing a first tier having therein a first portion of a micro architecture;
constructing a second tier having therein a second portion of said micro architecture, said first and second portions requiring close communication;
coupling said second tier to said first tier; and
constructing a series of vias through at least one of said tiers to allow for communication between said first and second portions.

8. The method of claim 7 wherein said micro architecture comprises at least one memory element and at least one micro-processor element.

9. The method of claim 8 wherein said memory element is a register utilized by said micro-processor element.

10. The method of claim 7 wherein said first and second portions of said micro-architecture are manufactured under processes independent from each other.

11. An IC device comprising:
a first tier having constructed therein memory elements along a plane of said tier;
a second tier stacked with said first tier within said IC device, said second tier having constructed therein a micro-processor relying on close coupling with said memory elements for operation; and
a series of connections distributed about said plane of said first tier, said connections enabling said close coupling.

12. The IC device of claim 11, wherein said series of connections comprises through silicon vias (TSVs).

13. The IC device of claim 11, wherein said series of connections comprises direct die-to die bonding structures.

14. The IC device of claim 11 further comprising:
a second micro-processor constructed in said second tier, said second micro-processor close-coupled to said memory elements for operation.

15. The IC device of claim 14 further comprising:
a second memory constructed in said first tier, said second memory having close coupling with said second micro-processor.

16. The IC device of claim 11 wherein said first and second tiers are constructed using separate processes.

17. A method for constructing an IC device, said method comprising:
constructing a first tier of said IC device using a first process, said first process compatible with creation within said first tier of a first set of elements;
constructing a second tier of said IC device using a second process, said second process compatible with creation within said second tier of a second set of elements in a same pipeline stage as said first set of elements; and
bonding said first and second tiers together to form at least a portion of said IC device, said bonding facilitating close-coupled communication between certain of said first and second element sets, wherein one of said element sets are memories and the other of said element sets are devices which require close coupling with said memory.

18. The method of claim 17 further comprising constructing in at least one of the tiers a plurality of through silicon vias (TSVs) for facilitating said close coupling.

19. A method for constructing an IC device, said method comprising:
constructing a first semi-conductor tier having therein a first set of elements of a pipeline stage;
constructing a second semi-conductor tier having therein a second set of elements of the pipeline stage, and
bonding said first and second semi-conductors together to form at least a portion of said IC device, said bonding facilitating close-coupled communication between certain of said first and second element sets which require close coupling.

20. The method of claim 19 further comprising constructing a plurality of through silicon vias (TSVs) in at least one of said tiers for facilitating said close coupling.

21. The method of claim 19 further comprising constructing direct die-to-die bonding structures for facilitating said close coupling.
